(19) United States
(12) Patent Application Publication
(10) Pub. No.: US 2014/0159238 A1
(43) Pub. Date: Jun. 12, 2014

(54) PACKAGE HAVING THERMAL COMPRESSION FLIP CHIP (TCFC) AND CHIP WITH REFLOW BONDING ON LEAD

(71) Applicant: QUALCOMM INCORPORATED, San Diego, CA (US)

(72) Inventors: Manuel Aldrete, San Diego, CA (US); Milind P. Shah, San Diego, CA (US); Omar J. Bchir, San Diego, CA (US); Houssam W. Jomaa, San Diego, CA (US); Chin-Kwan Kim, San Diego, CA (US)

(73) Assignee: QUALCOMM Incorporated, San Diego, CA (US)

(21) Appl. No.: 13/708,221

(22) Filed: Dec. 7, 2012

(51) Int. Cl. H01L 23/488; H01L 23/00

(52) U.S. Cl. CPC H01L 23/488; H01L 24/80
USPC 257/741; 228/175; 228/44.7; 228/102

(57) ABSTRACT

Some exemplary implementations of this disclosure pertain to an integrated circuit package that includes a substrate, a first die and a second die. The substrate includes a first set of traces and a second set of traces. The first set of traces has a first pitch. The second set of traces has a second pitch. The first pitch is less than the second pitch. In some implementations, a pitch of a set of traces defines a center to center distance between two neighboring traces, or bonding pads on a substrate. The first die is coupled to the substrate by a thermal compression bonding process. In some implementations, the first die is coupled to the first set of traces of the substrate. The second die is coupled to the substrate by a reflow bonding process. In some implementations, the second die is coupled to the second set of traces of the substrate.

### FIELD

Various features relate to a package having a thermal compression flip chip (TCFC) and a chip with reflow bonding on lead.

### BACKGROUND

A thermal compression bonding process is a process used to assemble/package a flip chip, die or semiconductor device to a packaging substrate. Such a flip chip is often referred to as a thermal compression flip chip (TCFC). Thermal compression bonding processes provide several advantages over traditional bonding processes. For example, thermal compression bonding processes are generally more accurate than other solder bonding processes. Thus, thermal compression bonding processes are ideal when using fine pitch traces on a substrate (e.g., less than 100 microns (μn)). In contrast, other solder bonding processes are limited to a bonding pitch that is greater than 100 microns (μm). Thus, TCFCs are typically higher density chips than chips using other bonding processes.

FIG. 1 illustrates an example of a chip/die coupled to a substrate using a thermal compression bonding process. As shown in FIG. 1, a chip 102 is coupled to a substrate 100. There are several electrical connections between the chip 102 and the packaging substrate 100. These electrical connections may be defined as under bump metallization (UBM) structures, solder and traces. These electrical connections are conceptually represented by components 104. There is also a non-conductive paste (NCP) 106 between the chip 102 and the substrate 100. The NCP 106 provides a protective layer that covers the electrical connections 104 between the chip 102 and the substrate 100.

FIGS. 2-4 illustrate an example of a sequence of how a chip/die may be assembled to a package by using a thermal compression bonding process. The top portion of FIG. 2 illustrates a package 200 that a die may be mounted on using a thermal compression bonding process. The package 200 includes a packaging substrate 202 and several traces 203a-c. FIG. 2 also illustrates a non-conductive paste (NCP) 201, which has been dispensed on top of the traces 203a-c. The NCP 201 is dispensed before a thermal compression bonding process is done.

The bottom portion of FIG. 2 illustrates a die 208 that is being coupled to the package 200. As shown in FIG. 2, the die 208 is coupled to a heater 210. The die 208 includes several bumps 204a-e. Each of the bumps 204a-c respectively includes copper pillars 205a-c. Each bumps 204a-c may also respectively include solders 206a-c.

FIG. 3 illustrates the thermal compression bonding process being applied to the die 208. Specifically, FIG. 3 illustrates that after the die 208 has been place on the packaging substrate 202, and the bumps 204a-c are properly aligned with the traces 203a-c, the heater 210 heats the die 208 and the bumps 204a-c, thereby coupling the die 208 to the package 200. FIG. 4 illustrates the die 208 coupled to the package 200. Specifically, FIG. 4 illustrates the heater 210 being removed from the die 208 once the die 208 has been coupled to the package 200 using a thermal compression bonding process. In some implementations, pressure may also be applied in order to couple the die 208 to the package 200.

FIG. 5 illustrates several TCFCs coupled to a package. As shown in FIG. 5, the package 500 includes a substrate 502, a first thermal compression flip chip (TCFC) 504, a second TCFC 506, and a third TCFC 508. In some implementations, the package 500 is an integrated circuit package, such as a System-in-Package (SiP). Each of the first, second, and third chips 504-508 has been coupled to the substrate 502 using a thermal compression bonding process. One of the characteristics of a thermal compression bonding process is that each chip must be bonded to the substrate one at a time. That is, each TCFC must be placed on the substrate and heated before another TCFC can be placed on the substrate and heated. In other words, TCFCs are coupled to a package in series and not in parallel. This is problematic because the process of coupling several TCFCs to a package can be expensive if each bonding process must be done in series.

Moreover, the thermal compression bonding process can take a lot of time. In fact, relative to other bonding processes, the thermal compression bonding process has a very low unit per hour (UPH) value. A UPH value specifies how many units of something (e.g., die) can be produced/created in a given amount of time. Thus, despite the fact that a thermal compression bonding process can be used with substrates having fine pitch traces, using such a process may not be desirable, where it may not be needed, due to the cost and time associated with coupling several chips to a package.

Therefore, there is a need for a package that includes several chips, where the package can be manufactured very quickly, efficiently and at a lower cost than exclusively using a thermal compression bonding process.

### SUMMARY

Various features relate to a package having a thermal compression flip chip (TCFC) and a chip with reflow bonding on lead.

A first example provides an integrated circuit (IC) package that includes a substrate, a first die and a second die. The substrate includes a first set of traces and a second set of traces. The first set of traces has a first pitch. The second set of traces has a second pitch. The first pitch is less than the second pitch. In some implementations, a pitch defines a center to center distance between two neighboring traces. The first die is coupled to the substrate by a thermal compression bonding process. The first die is coupled to the first set of traces of the substrate. The second die is coupled to the substrate by a reflow bonding process. The second die is coupled to the second set of traces of the substrate.

According to one aspect, the IC package includes a copper bond on lead located between the second die and the substrate. The copper bond on lead provides an electrical path for the die. In some implementations, the IC package further includes a non-conductive epoxy layer located between the first die and the substrate. The non-conductive epoxy layer provides a protective layer for a joint between the first die and the substrate.

According to another aspect, the IC package further includes a third die coupled to the substrate by the reflow bonding process. In some implementations, the reflow bonding process is concurrently applied to the second die and the third die after the first die is coupled to the substrate by the thermal compression bonding process.

According to yet another aspect, the first pitch is a pitch of less than 100 microns (μm) and the second pitch is a pitch of more than 100 microns (μm).

A second example provides a method for manufacturing an integrated circuit (IC) package. The method couples a first die to a substrate of the IC package by a thermal compression bonding process. The method further couples a second die to the substrate of the IC package by a reflow bonding process.

According to one aspect, the substrate has a first set of traces and a second set of traces. In some implementations, the first set of traces has a first pitch and the second set of traces has a second pitch. The first pitch is less than the second pitch. In some implementations, a pitch defines a center to center distance between two neighboring traces. In some implementations, the first pitch is pitch of 100 microns (μm) or less and the second pitch is a pitch of more than 100 microns (μm).

According to another aspect, coupling the first die to the substrate includes coupling the first die to the first set of traces of the substrate. In some implementations, coupling the second die to the substrate includes coupling the second die to the second set of traces of the substrate.

According to yet another aspect, the method further includes coupling a third die to the substrate of the IC package by the reflow bonding process, where the second die and the third die are coupled to the substrate in parallel during the same reflow bonding process. In some implementations, the reflow bonding process is concurrently applied to the second die and the third die after the first die is coupled to the substrate by the thermal compression bonding process. In some implementations, the thermal compression bonding process has a lower units per hour (UPH) value than the UPH value of the reflow bonding process. In some implementations, the UPH value defines a number of units that can be manufactured during a given amount of time.

According to one aspect, the first die has a first density connection with the substrate. The second die has a second density connection with the substrate. The second density connection is less than the first density connection.

A third example provides an apparatus for manufacturing an integrated circuit (IC) package. The apparatus includes means for coupling a first die to a substrate of the IC package by a thermal compression bonding process. The apparatus also includes means for coupling a second die to the substrate of the IC package by a ram bonding process.

According to one aspect, the substrate has a first set of traces and a second set of traces. The first set of traces has a first pitch and the second set of traces has a second pitch. The first pitch is less than the second pitch. In some implementations, a pitch defines a center to center distance between two neighboring traces. In some implementations, the first pitch is a pitch of 100 microns (μm) or less and the second pitch is a pitch of more than 100 microns (μm).

According to another aspect, the apparatus further includes means for coupling a third die to the substrate of the IC package by the reflow bonding process. In some implementations, the second die and the third die are coupled to the substrate in parallel during the same reflow bonding process. In some implementations, the reflow bonding process is concurrently applied to the second die and the third die after the first die is coupled to the substrate by the thermal compression bonding process.

According to another aspect, the thermal compression bonding process has a lower units per hour (UPH) value than the UPH value of the reflow bonding process. In some implementations, the UPH value defines a number of units that can be manufactured during a given amount of time.

A fourth example provides a computer readable storage medium comprising one or more instructions for manufacturing an integrated circuit (IC) package, which when executed by at least one processor, causes the at least one processor to couple a first die to a substrate of the IC package by a thermal compression bonding process, and couple a second die to the substrate of the IC package by a reflow bonding process.

According to one aspect, the substrate has a first set of traces and a second set of traces. The first set of traces has a first pitch and the second set of traces has a second pitch. The first pitch is less than the second pitch. In some implementations, a pitch defines a center to center distance between two neighboring traces. In some implementations, the first pitch is a pitch of 100 microns (μm) or less and the second pitch is a pitch of more than 100 microns (μm).

### DRAWINGS

Various features, nature and advantages may become apparent from the detailed description set forth below when taken in conjunction with the drawings in which like reference characters identify correspondingly throughout.

FIG. 1 illustrates a thermal compression flip chip coupled to a packaging substrate.

FIG. 2 illustrates a thermal compression flip chip being attached to a packaging substrate.

FIG. 3 illustrates a thermal heating being applied to bond a thermal compression flip chip to a packaging substrate.

FIG. 4 illustrates a heater being removed from a thermal compression flip chip (die).

FIG. 5 illustrates a package that includes several thermal compression flip chips.

FIG. 6 illustrates a package that includes a thermal compression flip chip and several reflow bonding on lead chips.

FIG. 7 illustrates a flow diagram of a method for manufacturing a package that includes a thermal compression flip chip and a reflow bonding on lead chip.

FIGS. 8A-8C illustrate a sequence for manufacturing a package that includes a thermal compression flip chip and several reflow bonding on lead chips.

FIGS. 9A-9B illustrate a flow diagram of a detailed method for manufacturing a package that includes a thermal compression flip chip and a reflow bonding on lead chip.

FIG. 10 illustrates various electronic devices that may integrate the IC described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

### Overview

Some exemplary implementations of this disclosure pertain to an integrated circuit package that includes a substrate, a first die and a second die. The substrate includes a first set of traces and a second set of traces. The first set of traces has a first pitch. The second set of traces has a second pitch. The first pitch is less than the second pitch. In some implementations, a pitch of a set of traces defines a center to center distance between two neighboring traces, or bonding pads on a substrate. The first die is coupled to the substrate by a thermal compression bonding process. In some implementations, the first die is coupled to the first set of traces of the substrate. The second die is coupled to the substrate by a reflow bonding process. In some implementations, the second die is coupled to the second set of traces of the substrate. In some implementations, the first pitch may be a pitch of 100 microns (μm) or less. The second pitch may be a pitch of more than 100 microns (μm) in some implementations.

Some exemplary implementations of this disclosure pertain to a method for manufacturing an integrated circuit (IC) package. The method couples a first die to a substrate of the IC package by a thermal compression bonding process. The method also couples a second die to the substrate of the IC package by a reflow bonding process. In some implementations, the substrate has a first set of traces and a second set of traces. The first set of traces has a first pitch and the second set of traces has a second pitch. The first pitch is less than the second pitch. In some implementations, the method also couples a third die to the substrate of the IC package by the ram bonding process. The second die and the third die may be coupled to the substrate in parallel during the same reflow bonding process. In some implementations, the reflow bonding process is concurrently applied to the second die and the third die after the first die is coupled to the substrate by the thermal compression bonding process.

Exemplary Package with Thermal Compression Flip Chip and Reflow Bonding on Lead Chip

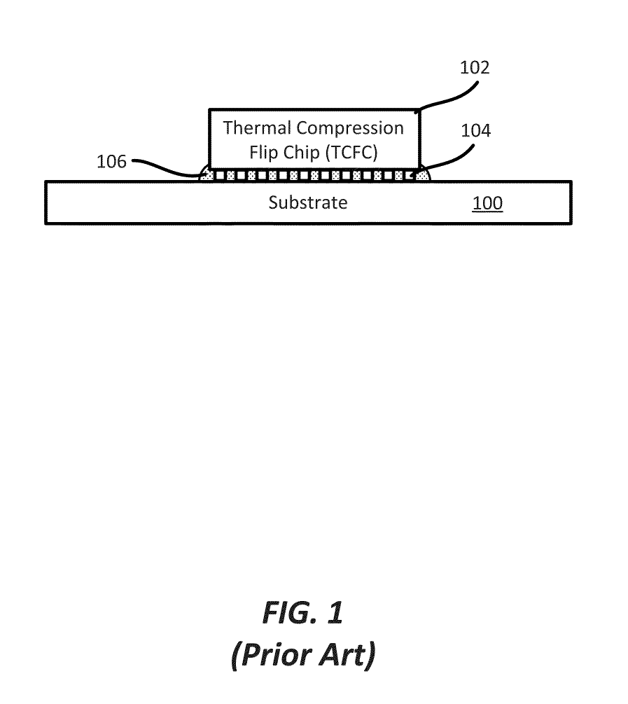

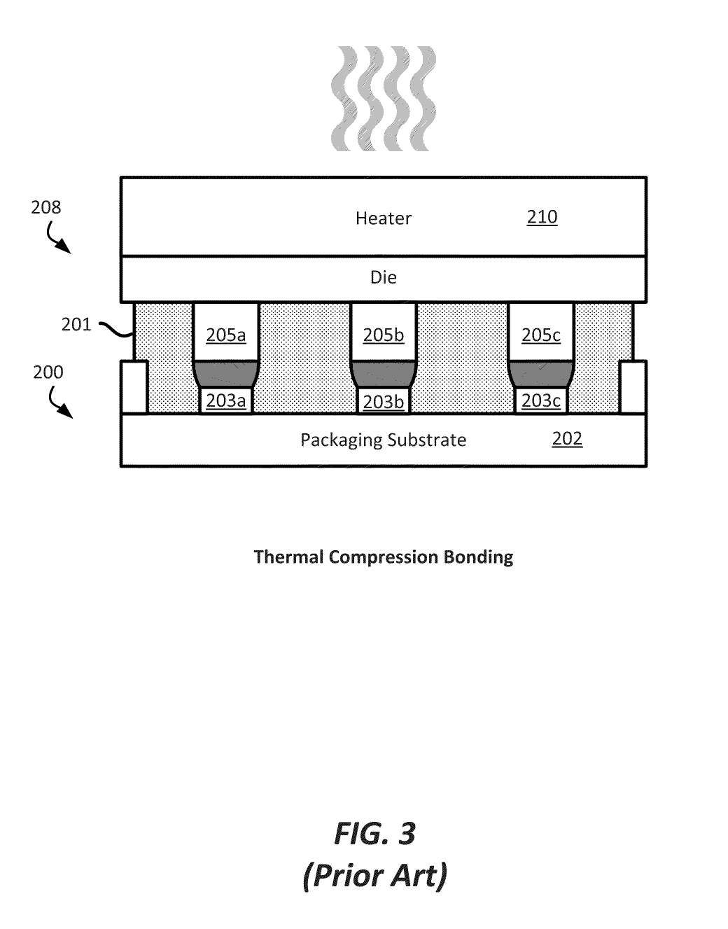

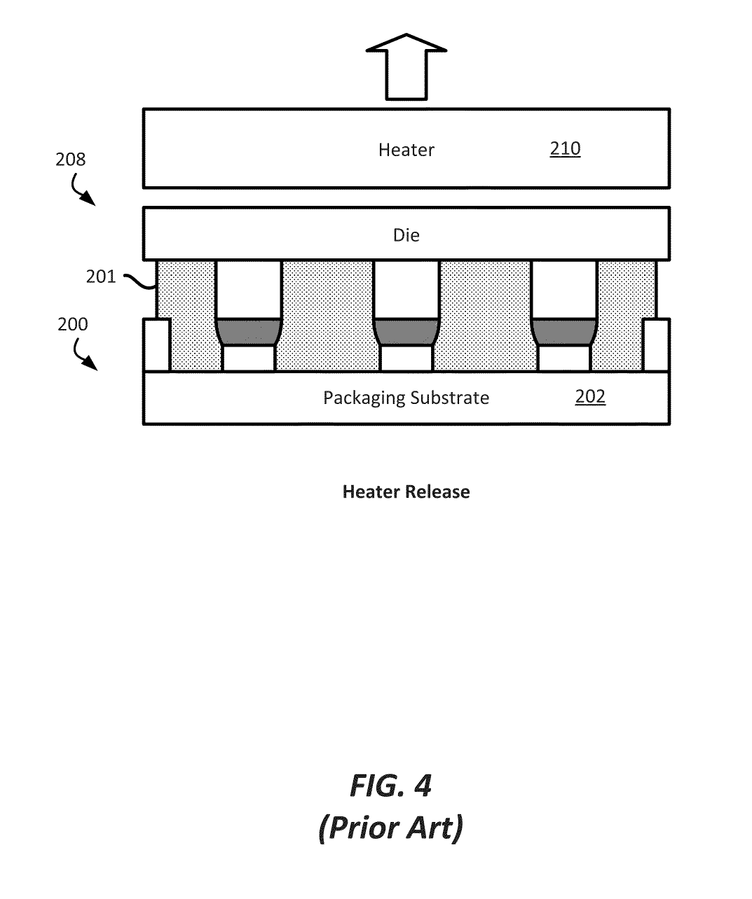

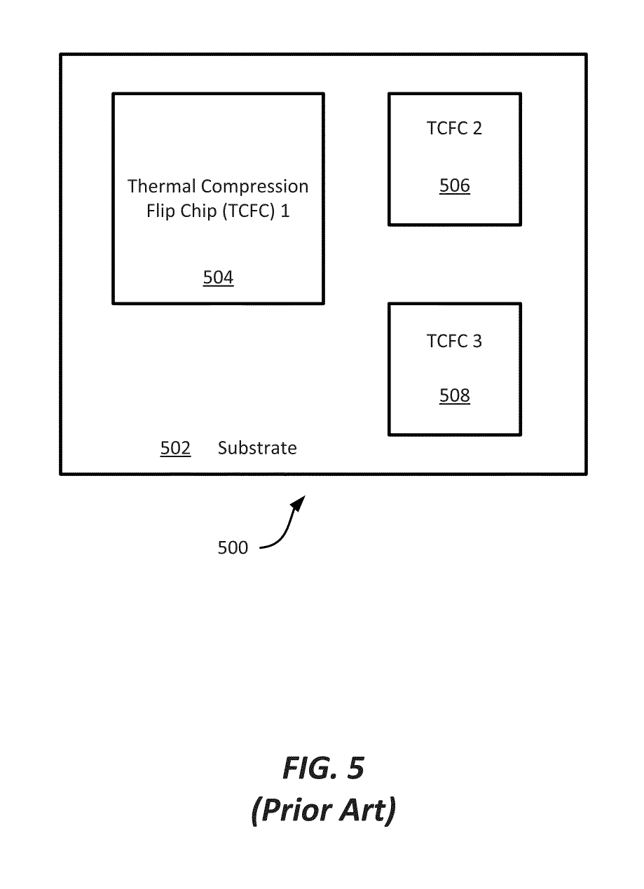

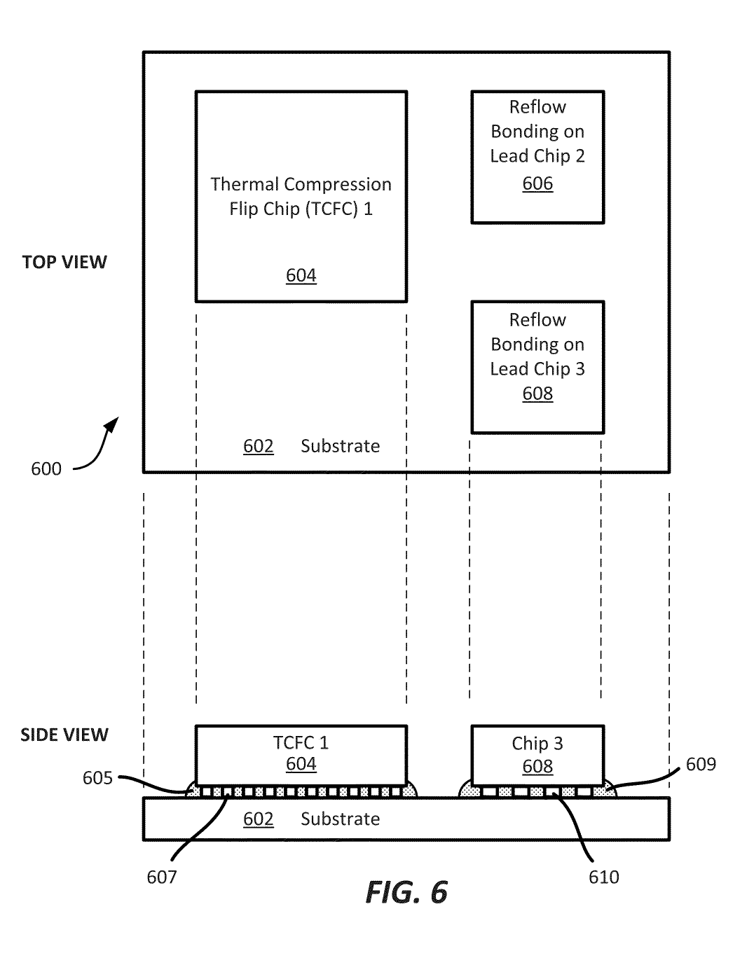

FIG. 6 illustrates a package that includes several chips/dice. Specifically, FIG. 6 illustrates a package 600 that includes a substrate 602, a first thermal compression flip chip (TCFC) 604, a second chip 606, and a third chip 608. In some implementations, the package 600 is an integrated circuit package, such as a System-in-Package (SiP). The first chip 604 is coupled to the substrate 602 using a thermal compression bonding process, such as the one described in FIGS. 1-4. As shown in FIG. 6, there is a non-conductive epoxy layer 605 between the first chip 604 and the substrate 602. The non-conductive epoxy layer 605 may be a non-conductive paste (NCP) in some implementations. In some implementations, the non-conductive epoxy layer 605 may be a non-conductive film. The epoxy layer 605 provides a protective layer that covers the electrical connections between the first chip 604 and the substrate 602. In some implementations, the electrical connections between the first chip 604 and the substrate 602 are defined by under bump metallization (UBM) structures, solder and traces. These electrical connections are conceptually represented by components 607 in FIG. 6.

FIG. 6 also illustrates that the second chip 606 and the third chip 608 are coupled to the substrate 602 using a bonding process that is different than a thermal compression bonding process. In some implementations, the second chip 606 and the third chip 608 are coupled to the substrate 602 using a reflow bonding process, such as a reflow bonding on lead (RBL) process. As further shown in FIG. 6, there is underfill material 609 between the third chip 608 and the substrate 602. The underfill material 609 may also provide a protection layer that covers the electrical connections between the third chip 608 and the substrate 602. In some implementations, the electrical connections between the third chip 608 and the substrate 602 are defined by under bump metallization (UBM) structures, solder and traces. These electrical connections are conceptually represented by components 610 in FIG. 6. In some implementations, one difference between the electrical connections 607 of the first chip 604 and the electrical connections 610 of the third chip 608 is the distance (e.g., pitch) between the electrical connections. In the case of electrical connections 607, the distance (e.g., pitch) is smaller (e.g., narrower) than the distance of the electrical connections 610 of the third chip 608. This is because in some implementations, a thermal compression bonding process is more accurate than a reflow bonding process. As such, the pitch between electrical connections (e.g., pitch between traces) can be smaller in a thermal compression bonding process than a reflow bonding process, which is one benefit of using a thermal compression bonding process. In some implementations, having smaller pitches means that a die/chip using a thermal compression bonding process may have higher connectivity density (e.g., higher number of electrical connections in a given area) than a die/chip that uses a reflow bonding process.

However, the advantage of a ram bonding process is that multiple chips can be coupled to a substrate at the same time. In other words, the reflow bonding process can be performed in parallel (e.g., concurrently) on several chips. Consequently, the reflow bonding process has a higher units per hour (UPH) value than the UPH value of a thermal compression bonding process. Thus, in cases where several chips need to be coupled to a substrate of a package, the reflow bonding process will be able to bond chips to the substrate at a faster rate than the thermal compression bonding process. This not only saves time, but cost as well. In one example, a reflow bonding process may be a reflow bonding on lead (RBL) process, which may be used with a chip with a copper bond on lead. In some implementations, such a die or chip coupled to a packaging substrate may be referred to as a CuBoL chip/die. In some embodiments, copper bond on lead refers to the use of at least one copper column on the die/chip side and at least one trace on the substrate side. Copper bond on lead provides several advantages including not requiring a solder mask, defined pads or solder pads on the substrate side in some implementations.

Notwithstanding the above, it may still be desirable to use a thermal compression bonding process on some of the chips (e.g., high density chip and/or when chip requires fine pitch) on a package.

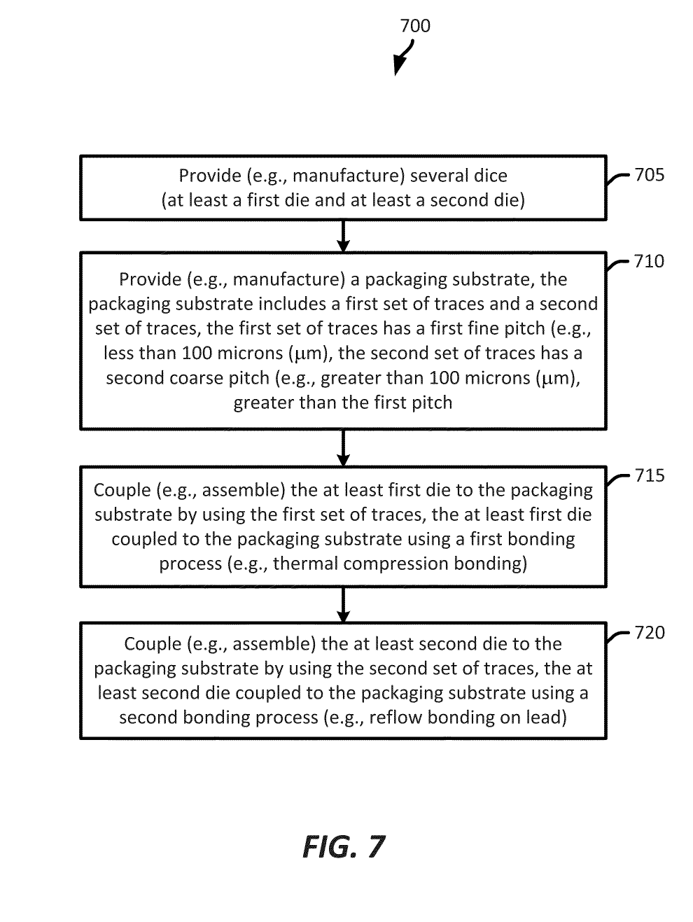

Having described a package that includes a thermal compression flip chip and a reflow bonding on lead chip, a method for manufacturing such a package will now be described below with reference to FIGS. 7, 8A-8C, and 9A-9B.

Exemplary Method for Manufacturing a Package that Includes a Thermal Compression Flip Chip (TCFC) and a Reflow Bonding on Lead (RBL) Chip

FIG. 7 illustrates a flow diagram of an overview method for manufacturing/assembling a package that includes a thermal compression flip chip (TCFC) and a reflow bonding on lead (RBL) chip (e.g., copper on lead (CuBoL) chip) in some implementations.

The method begins by providing (at 705) several dice. In some implementations, providing (at 705) several dices include manufacturing several dice. In some implementations, providing several dice includes providing (e.g., manufacturing) at least one first die/chip that has several UBM structures having a first pitch (e.g., fine pitch). In addition, providing manufacturing) the dice may include providing (e.g., manufacturing) at least one second die/chip that has several UBM structures having a second pitch (e.g., coarse pitch) in some implementations.

Next, the method provides (at 710) a packaging substrate. In some implementations, providing (at 710) a packaging substrate includes manufacturing a packaging substrate. The packaging substrate may serve as the base of the package in some implementations. The package may be a system-in-package (SiP) in some implementation. Providing (at 710) the packaging substrate may include providing (e.g., defining) a first set of traces and a second set of traces on the packaging substrate. The first set of traces may have a first pitch (e.g., less or equal than 100 microns (μm)), while the second set of traces may have a second pitch (e.g., more than 100 microns (μm)) in some implementations.

The method then couples (at 715) at least one first die to the packaging substrate using a first bonding process. In some implementations, coupling the first die to the packaging substrate includes assembling the first die to the packaging substrate by a thermal compression bonding process (such as the one described in FIGS. 1-4 for example). In some implementations, coupling the first die the packaging substrate includes coupling the first die to the first set of traces of the packaging substrate.

After coupling (at 715) the first die, the method couples (at 720) at least one second die to the packaging substrate by a second bonding process and ends. In some implementations, coupling the second die to the packaging substrate includes assembling the second die to the packaging substrate by a reflow bonding process. Using a reflow bonding process may result in a reflow bonding on lead (RBL) chip (e.g., copper on lead (CuBoL) chip) in some implementations. In some implementations, multiples second dice are coupled in parallel (e.g., concurrently) to the packaging substrate. In some implementations, coupling the second die to the packaging substrate includes coupling the second die to the second set of traces of the packaging substrate.

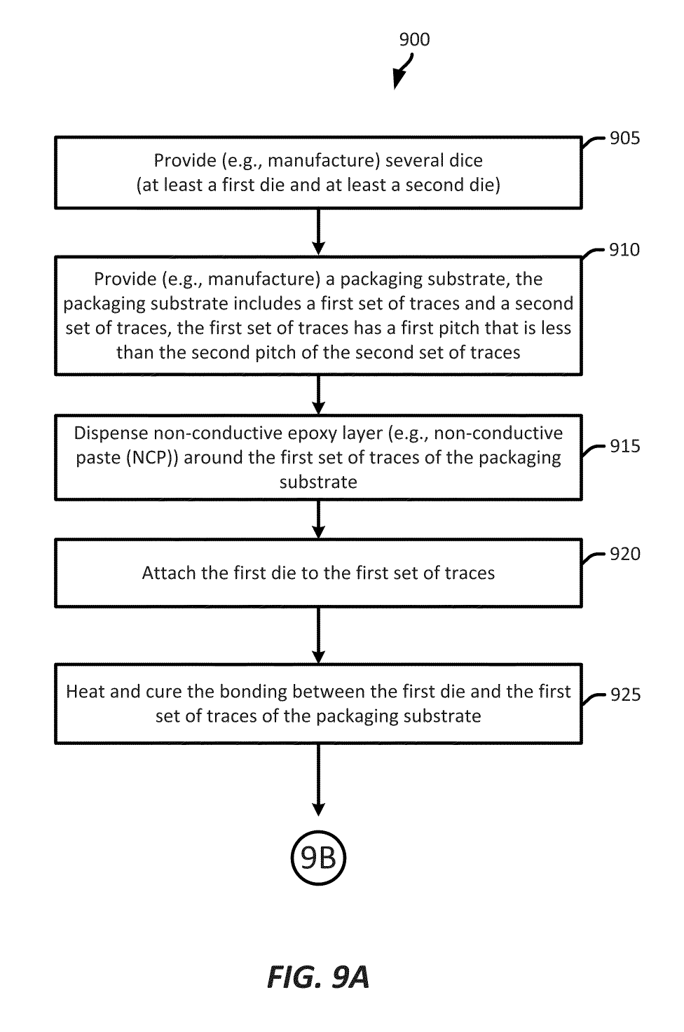

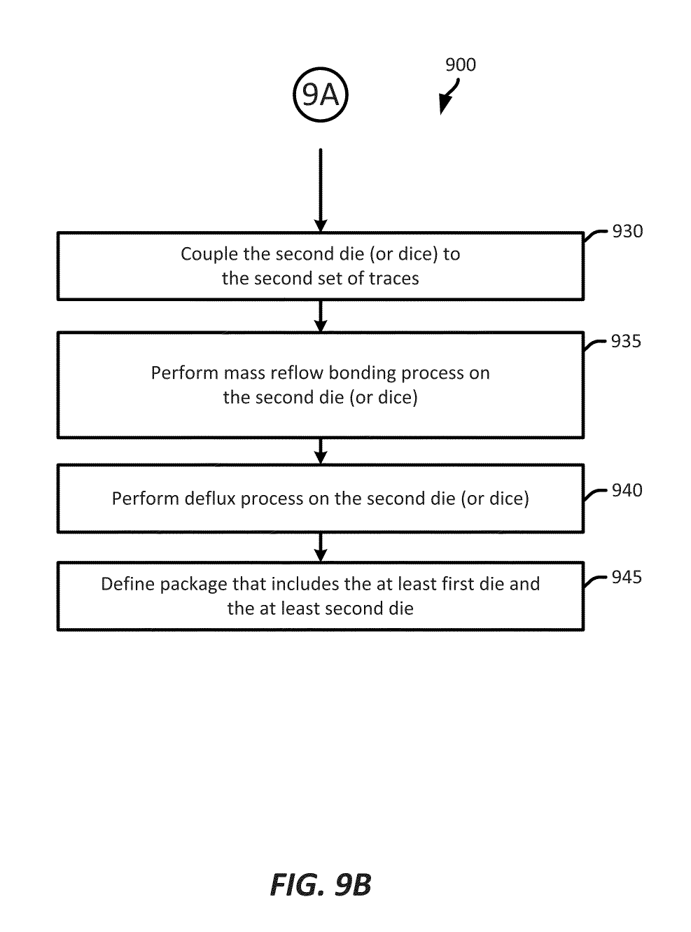

A more detailed method for providing/manufacturing a package that includes a thermal compression flip chip and a reflow bonding on lead chip will be further described below with reference to FIGS. 9A-9B. However, a visual sequence of how a package that includes a thermal compression flip chip and at least one copper on lead chip is provided/assembled will first be described.

### Exemplary Sequence for Assembling a Package Using Two Different Bonding Processes

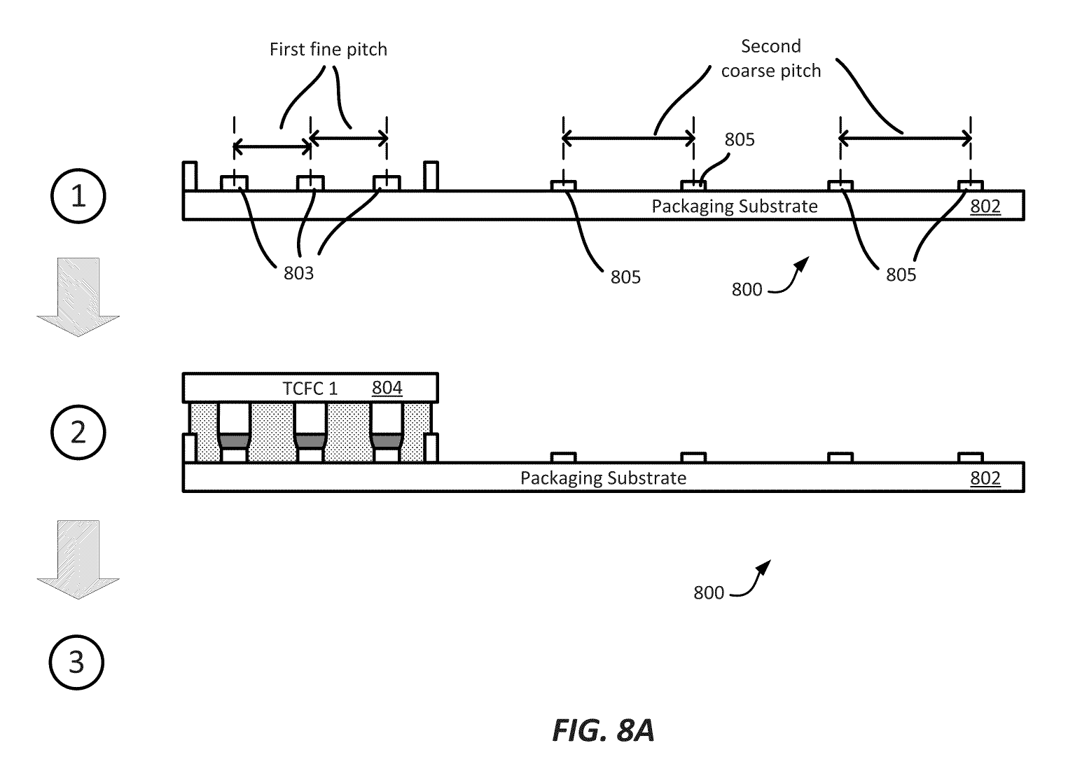

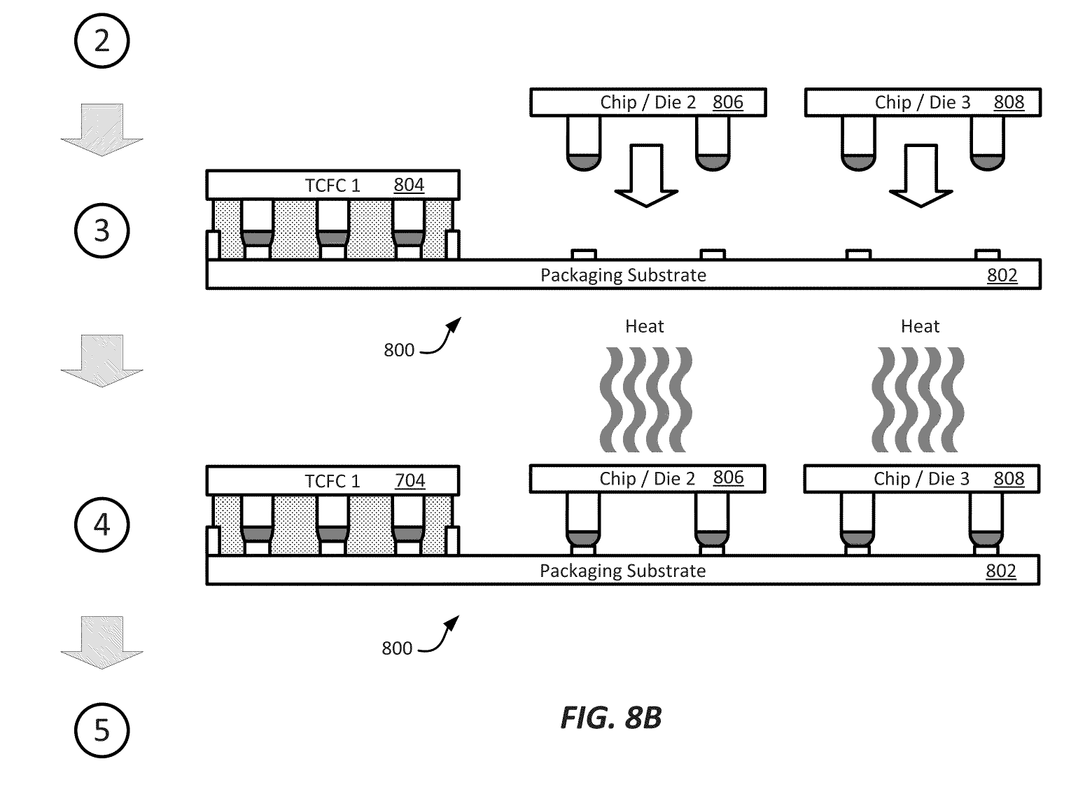

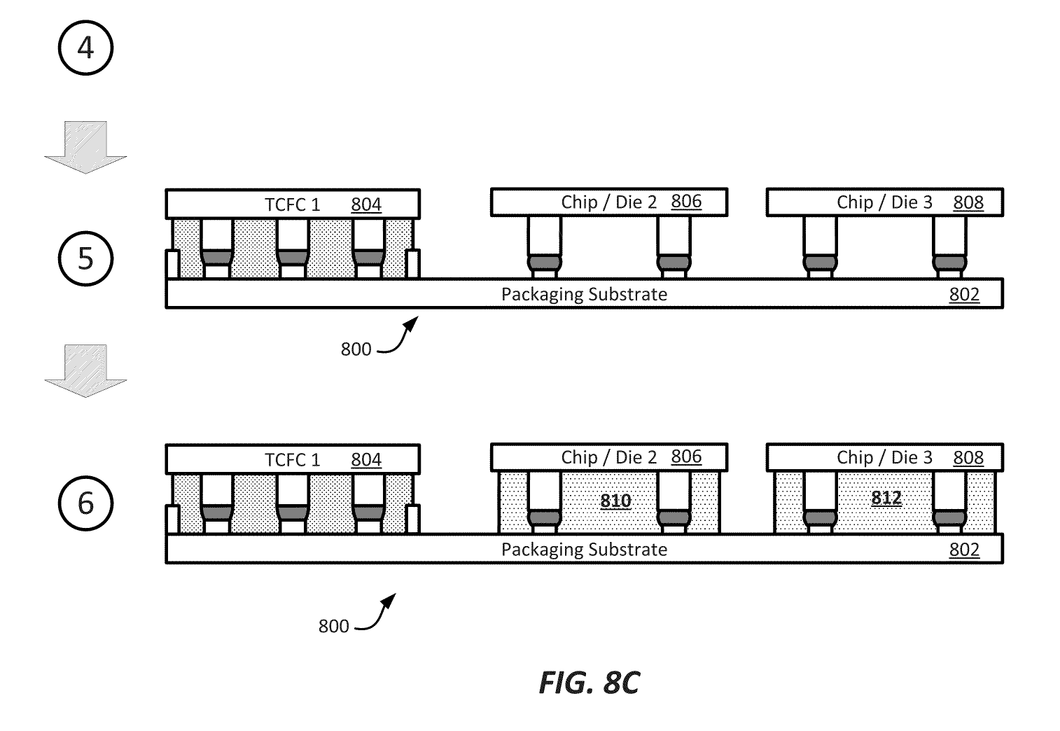

FIGS. 8A-8C illustrate a sequence of several chips being coupled to a substrate of a package in some implementations. It should be noted that for the purpose of clarity and simplification, the processes of FIGS. 8A-8C do not necessarily include all the steps and/or stages of providing/manufacturing/assembling a package. Moreover, in some instances, several steps and/or stages may have been combined into a single step and/or stage in order to simplify the description of the processes. In addition, the components illustrates in the FIGS. 8A-8C are merely conceptual illustrations and unless otherwise explicitly stated, do not necessarily represent the actual and/or relative dimensions of these components. In some instances, some of the dimensions may have been exaggerated to clearly illustrate/distinguish features of some of the components.

As shown in FIG. 8A, the assembly begins (at stage 1) with a packaging substrate 802 that includes a first set of traces 803 and a second set of traces 805. The first set traces 803 may have a first pitch (e.g., less or equal than 100 microns (μm)), while the second set of traces 805 may have a second pitch more than 100 microns (μm)) in some implementations.

The method then couples (at stage 2) a thermal compression flip chip (TCFC) 804 to the substrate 802. In some implementations, coupling the TCFC 804 to the substrate 802 includes using the thermal compression bonding process described above in FIGS. 1-4. As shown in stage 2, the TCFC 804 is coupled to the first set of traces 803 of the substrate 802.

Next, the method positions (at stage 3) several dice on the substrate 802. As shown in FIG. 8B, the second die 806 and the third die 808 are positioned about the second set of traces 805. The second die 806 and the third die 808 may be positioned on the substrate 802 sequentially (e.g., once after another) or they may be positioned on the substrate 802 concurrently. Different implementations may perform the positioning of the dice differently.

After positioning (at stage 3) the dice, the method heats (at stage 4) the dice 806-808 thereby coupling the dice 806-808 to the second set of traces 805 in some implementations. The heating of the dice may be referred to as the reflow bonding process in some implementations. The reflow bonding process may apply heat to the entire package (including TCFC 804, substrate 802) in some implementations. During the reflow bonding process, the heating of the dice 806-808 may also include the heating of the solder/joints that connect the dice 806-808 to the substrate 802. In some implementations, the joints refer to the part an electric connection between a die and a substrate. As described above, an electric connection between a die and substrate may be defined by a under bump metallization (UBM) structure, a solder and a trace. A joint may be defined as the connection between the UBM structure and the trace in some implementations (e.g., between solder and trace and/or between solder and UBM structure).

Stage 5 of FIG. 8C illustrates a substrate that includes several dice after a reflow bonding process. At stage 5, the heating performed during the reflow bonding process has set the joints between the dice 806-808 and the substrate 802.

In some implementations, after the reflow bonding process, the method may perform (at stage 6) a deflux operation, where flux is introduced in the area underneath the dice 806-808. In some implementations, the deflux operation may flow water under the die or dice to clean any flux residue that may be present under the die or dice (e.g., dice 806-808). After the deflux operation, the method may also perform (at stage 6) an underfill operation, where non-conductive epoxy layers 810-812 may each be respectively filled under each respective die 806-808. The non-conductive epoxy layers 810-812 may be a non-conductive paste (NCP) or a non-conductive film in some implementations.

In some implementations, the assembly process may include other operations, such as mold formation, ball attach, marking, and package singularization. Mold formation may include encapsulating the package to define the package. Ball attach may include coupling a solder ball grid array to the package. The ball grid array may allow the package to couple to a printed circuit board (PCB) in some implementations. In some implementations, the packages are assembled together in one large single substrate. During package singularization, the large substrate on which the packages are assembled/manufactured is divided in single packages in some implementations.

Exemplary Method for Providing, Manufacturing and Assembling a Package that Includes a Thermal Compression Flip Chip (TCFC) and a Reflow Bonding on Lead (RBL) Chip

FIGS. 9A-9B illustrates a flow diagram of a method for providing/manufacturing/assembling a package that includes a thermal compression flip chip (TCFC) and a reflow bonding on lead (RBL) chip (e.g., copper on lead (CuBoL) chip) in some implementations.

The method begins by providing (at 905) several dice. In some implementations, providing (at 905) several dice includes manufacturing several dice. In some implementations, providing the dice includes providing (e.g., manufacturing) at least one first die/chip that has several UBM structures having a first pitch (e.g., fine pitch). In addition, providing the dice may include providing (e.g., manufacturing) at least one second die/chip that has several UBM structures having a second pitch (e.g., coarse pitch) in some implementations.

Next, the method provides (at 910) a packaging substrate. In some implementations, providing (at 91) the packaging substrate includes manufacturing a packaging substrate. The packaging substrate may serve as the base of the package in some implementations. The package may be an integrated circuit package, such as a system-in-package (SiP) in some implementation. Providing (at 910) the packaging substrate may include providing (e.g., defining) a first set of traces and a second set of traces on the packaging substrate. The first set of traces may have a first pitch (e.g., less or equal than 100 microns (μm)), while the second set of traces may have a second pitch (e.g., more than 100 microns (μm)) in some implementations.

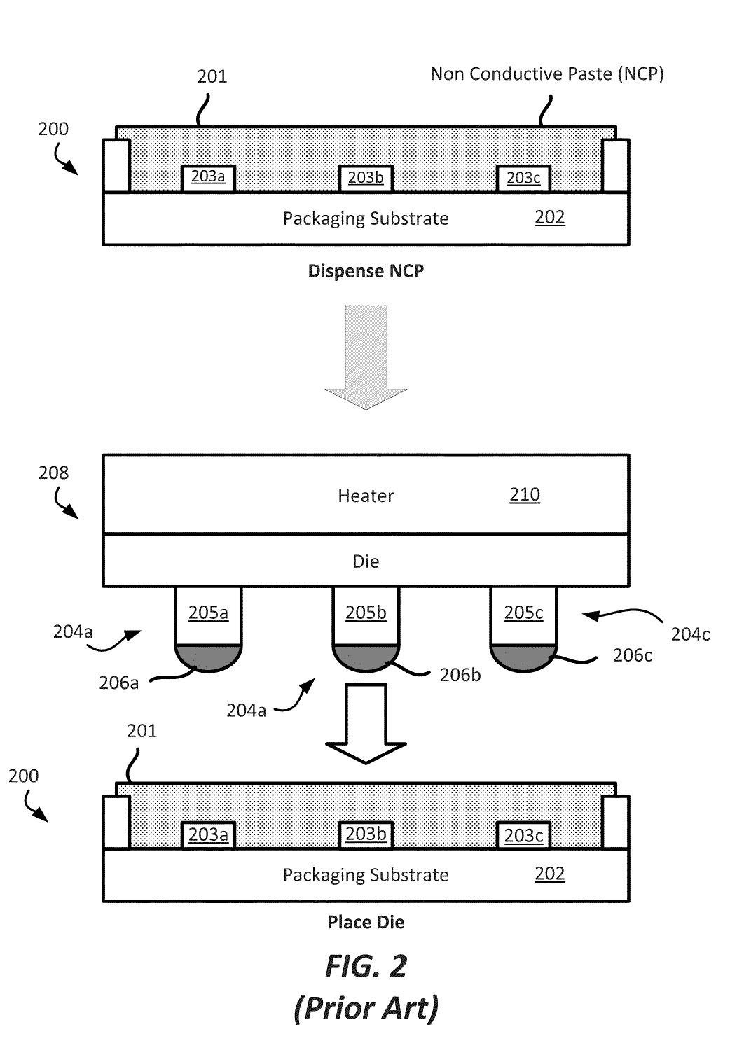

The method then dispenses (at 915) a non-conductive epoxy layer (e.g., non-conductive paste (NCP)) around a first set of traces on the packaging substrate. Next, the method attaches (at 920) the first die to the first set of traces. In some implementations, attaching (at 920) the first die includes positioning the first die above the first set of traces on the packaging substrate. FIG. 2 illustrates an example of the dispensing of an NCP (or any non-conductive epoxy layer) and the positioning of a first die.

Next, the method performs (at 925) a thermal compression bonding process on the first die. In some implementations, the thermal compression bonding process includes applying pressure and heating the first die. The heating of the first die may include the heating of the electrical connections and/or joints (e.g., solder between the first die and the substrate). In some instances, this may cause the solder to melt and bond the UBM structures to the first set of traces. Once the solder has cooled/cured, the joints securely and electrically couple the first die to the substrate in some implementations.

The method then couples (at 930) at least one second die to the packaging substrate. In some implementations, coupling (at 930) the second die includes positioning the second die on the second set of traces on the packaging substrate. After positioning (at 930) the second die, the method performs (at 935) a mass reflow bonding process on at least the second die (or dice). In some implementations, the mass reflow bonding process may be performed in parallel (e.g., concurrently) on several dice (e.g., several second dice) on the packaging substrate. The mass reflow bonding process may include applying pressure and heating one or more dice, including the electrical connections between the dice and the packaging substrate.

Next, the method performs (at 940) a deflux process on the at least one second die. In some implementations, the deflux process may include flowing water under at least the second die to clean any flux residue that may be present under the second die. The &flux operation may be performed in parallel on all mass reflow dice in some implementations.

After performing (at 940) the deflux process, the method defines (at 945) the package that includes the at least first die and the at least second die and ends. In some implementations, the defining (at 945) of the package may include dispensing underfill (e.g., non-conductive epoxy layer, NCP, non-conductive film) under one or more mass retlow dice (e.g., RBL chip), mold formation, ball attach, marking, and package singularization. Mold formation may include encapsulating the package. Ball attach may include coupling a solder ball grid array to the package. The ball grid array may allow the package to couple to a printed circuit board (PCB) in some implementations. In some implementations, the packages are assembled together in one large single substrate. During package singularization, the large substrate on which the packages are assembled/manufactured is divided in single packages in some implementations.

### Exemplary Electronic Devices

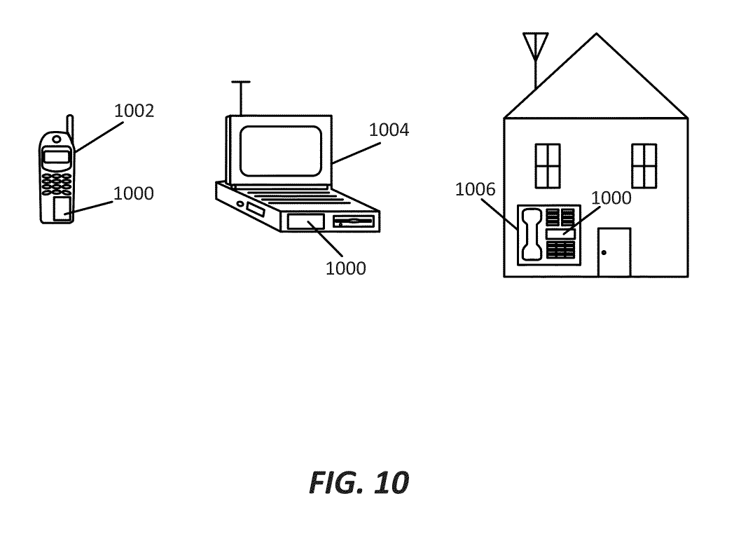

FIG. 10 illustrates various electronic devices that may be integrated with any of the aforementioned integrated circuit, die or package. For example, a mobile telephone 1002, a laptop computer 1004, and a fixed location terminal 1006 may include an integrated circuit (IC) 1000 as described herein. The IC 1000 may be, for example, any of the integrated circuits, dice or packages described herein. The devices 1002, 1004, 1006 illustrated in FIG. 10 are merely exemplary. Other electronic devices may also feature the IC 1000 including, but not limited to, hand-held personal communication systems (PCS) units, portable data units such as personal data assistants, GPS enabled devices, navigation devices, set top boxes, music players, video players, entertainment units, fixed location data units such as meter reading equipment, or any other device that stores or retrieves data or computer instructions, or any combination thereof.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another even if they do not directly physically touch each other. For instance, the substrate of the die may be coupled to the packaging substrate even though the substrate of the die is never directly physically in contact with the packaging substrate.

The terms wafer and substrate may be used herein to include any structure having an exposed surface with which to form an integrated circuit (IC) according to aspects of the present disclosure. The term die may be used herein to include an IC. The term substrate is understood to include semiconductor wafers. The term substrate is also used to refer to semiconductor structures during fabrication, and may include other layers that have been fabricated thereupon. The term substrate includes doped and undoped semiconductors, epitaxial semiconductor layers supported by a base semiconductor, or semiconductor layers supported by an insulator, as well as other semiconductor structures well known to one skilled in the art. The term insulator is defined to include any material that is less electrically conductive than materials generally referred to as conductors by those skilled in the art. The term “horizontal” is defined as a plane substantially parallel to the conventional plane or surface of a wafer or substrate, regardless of the orientation of the wafer or substrate. The term “vertical” refers to a direction substantially perpendicular to the horizontal as defined above, Prepositions, such as “on,” “upper,” “side,” “higher,” “lower,” “over,” and “under” when used with respect to the integrated circuits described herein are defined with respect to the conventional plane or surface being on the top surface of the wafer or substrate, regardless of the orientation of the wafer or substrate. The prepositions “on,” “upper,” “side,” “higher,” “lower,” “over,” and “under” are thereby defined with respect to “horizontal” and “vertical.”

One or more of the components, steps, features, and/or functions illustrated in FIGS. 6, 7, 8A-8C, 9A-9B and/or 10 may be rearranged and/or combined into a single component, step, feature or function or embodied in several components, steps, or functions. Additional elements, components, steps, and/or functions may also be added without departing from the invention.

Also, it should be noted that the figures of the disclosure are conceptual representations of dice/chips, packaging substrates and their components. As such, the figures are not necessarily exact representations of dice/chips and packaging substrates. In some or all of the figures, the dimensions of the dice/chips, packaging substrate, and/or components do not necessarily represent exact dimensions, unless otherwise explicitly stated in the disclosure.

Moreover, the figures of the disclosure do not necessarily include all components of the dice/chips and/or packaging substrates. In some instances, for the purpose of clarity and simplification, certain components of the dice/chips and/or packaging substrates may have been omitted from the figures. For example, a die/chip may include a substrate, several metal and dielectric layers, which are not shown in the figures. In addition, a solder resist layer (not shown) may be present on a packaging substrate and/or traces of the packaging substrate in some implementations.

Also, it is noted that the embodiments may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed. A process may correspond to a method, a function, a procedure, a subroutine, a subprogram, etc. When a process corresponds to a function, its termination corresponds to a return of the function to the calling function or the main function.

In addition, some or all of the methods and/or processes described for providing, manufacturing, coupling, and/or assembling the dice may be performed and/or controlled by one or more computers, devices, and/or apparatuses. These computers, devices, and/or apparatuses may include processors, processing circuits, circuits, and storage mediums for storing instructions.

Moreover, a storage medium may represent one or more devices for storing data, including read-only memory (ROM), random access memory (RAM), magnetic disk storage mediums; optical storage mediums, flash memory devices and/or other machine readable mediums for storing information. The terms “machine readable medium” or “machine readable storage medium” include, but is not limited to portable or fixed storage devices, optical storage devices, wireless channels and various other mediums capable of storing, containing or carrying instruction(s) and/or data.

Furthermore, embodiments may be implemented by hardware, software, firmware, middleware, microcode, or any combination thereof. When implemented in software, firmware, middleware or microcode, the program code or code segments to perform the necessary tasks may be stored in a machine-readable medium such as a storage medium or other storage(s). A processor may perform the necessary tasks. A code segment may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data; arguments, parameters, or memory contents. Information, arguments, parameters, data, etc. may be passed, forwarded, or transmitted via any suitable means including memory sharing, message passing, token passing, network transmission, etc.

The various illustrative logical blocks, modules, circuits (e.g., processing circuit), elements, and/or components described in connection with the examples disclosed herein may be implemented or performed with a general purpose processor, a digital signal processor (DSP), an application specific integrated circuit (ASIC), a field programmable gate array (FPGA) or other programmable logic component, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing components, e.g., a combination of a DSP and a microprocessor, a number of microprocessors, one or more microprocessors in conjunction with a DSP core, or any other such configuration.

The methods or algorithms described in connection with the examples disclosed herein may be embodied directly in hardware, in a software module executable by a processor, or in a combination of both, in the form of processing unit, programming instructions, or other directions, and may be contained in a single device or distributed across multiple devices. A software module may reside in RAM memory, flash memory, ROM memory, EPROM memory, EEPROM memory, registers, hard disk, a removable disk, a CD-ROM, or any other form of storage medium known in the art. A storage medium may be coupled to the processor such that the processor can read information from, and write information to, the storage medium. In the alternative, the storage medium may be integral to the processor.

Those of skill in the art would farther appreciate that the various illustrative logical blocks, modules, circuits, and algorithm steps described, in connection with the embodiments disclosed herein may be implemented as electronic hardware, computer software, or combinations of both. To clearly illustrate this interchangeability of hardware and software, various illustrative components, blocks, modules, circuits, and steps have been described, above generally in terms of their functionality. Whether such functionality is implemented as hardware or software depends upon the particular application and design constraints imposed on the overall system.

The various features of the disclosure described, herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. An integrated circuit (IC) package comprising:
a substrate comprising a first set of traces and a second set of traces, the first set of traces having a first pitch, the second set of traces having a second pitch, the first pitch being less than the second pitch, wherein a pitch defines a center to center distance between two neighboring traces;
a first die coupled to the substrate by a thermal compression bonding process, the first die coupled to the first set of traces of the substrate; and
a second die coupled to the substrate by a reflow bonding process, the second die coupled to the second set of traces of the substrate.

2. The IC package of claim 1, wherein the first pitch is a pitch of 100 microns (μm) or less, the second pitch having a pitch of more than 100 microns (μm).

3. The IC package of claim 1, further comprising a copper bond on lead located between the second die and the substrate, the copper bond on lead providing an electrical path for the die.

4. The IC package of claim 1, further comprising a non-conductive epoxy layer located between the first die and the substrate, the non-conductive epoxy layer providing a protective layer for a joint between the first die and the substrate.

5. The IC package of claim 1, wherein the thermal compression bonding process has a lower units per hour (UPH) value than a UPH value of the reflow bonding process, the UPH value defining a number of units that can be manufactured during a given amount of time.

6. The IC package of claim 1, wherein the first die has a first density connection with the substrate, the second die having a second density connection with the substrate that is less than the first density connection.

7. The IC package of claim 1, wherein the first die is coupled to the substrate before the second die during an assembly process of the IC package.

8. The IC package of claim 1, further comprising a third die coupled to the substrate by the reflow bonding process.

9. The IC package of claim 8, wherein the reflow bonding process is concurrently applied to the second die and the third die.

10. The IC package of claim 9, wherein the reflow bonding process is concurrently applied to the second die and the third die after the first die is coupled to the substrate by the thermal compression bonding process.

11. A method for manufacturing an integrated circuit (IC) package, comprising:
coupling a first die to a substrate of the IC package by a thermal compression bonding process; and
coupling a second die to the substrate of the IC package by a reflow bonding process.

12. The method of claim 11, wherein the substrate has a first set of traces and a second set of traces, the first set of traces having a first pitch, the second set of traces having a second pitch, the first pitch being less than the second pitch, wherein a pitch defines a center to center distance between two neighboring traces.

13. The method of claim 12, wherein the first pitch is a pitch of 100 microns (μm) or less, the second pitch having a pitch of more than 100 microns (μm).

14. The method of claim 12, wherein coupling the first die to the substrate comprises coupling the first die to the first set of traces of the substrate.

15. The method of claim 12, wherein coupling the second die to the substrate comprises coupling the second die to the second set of traces of the substrate.

16. The method of claim 11 further comprising coupling a third die to the substrate of the IC package using the reflow bonding process, wherein the second die and the third die are coupled to the substrate in parallel during the same reflow bonding process.

17. The method of claim 16, wherein the reflow bonding process is concurrently applied to the second die and the third die after the first die is coupled to the substrate by the thermal compression bonding process.

18. The method of claim 11, wherein the first die is coupled to the substrate before the second die during an assembly process of the IC package.

19. The method of claim 11, wherein the thermal compression bonding process has a lower units per hour (UPH) value than a UPH of the reflow bonding process, the UPH value defining a number of units that can be manufactured during a given amount of time.

20. The method of claim 11, wherein the first die has a first density connection with the substrate, the second die having a second density connection with the substrate that is less than the first density connection.

21. An apparatus for manufacturing an integrated circuit (IC) package, comprising:
means for coupling a first die to a substrate of the IC package by a thermal compression bonding process; and
means for coupling a second die to the substrate of the IC package by a reflow bonding process.

22. The apparatus of claim 21, wherein the substrate has a first set of traces and a second set of traces, the first set of traces having a first pitch, the second set of traces having a second pitch, the first pitch being less than the second pitch, wherein a pitch defines a center to center distance between two neighboring traces.

23. The apparatus of claim 22, wherein the first pitch is a pitch of 100 microns (μm) or less, the second pitch having a pitch of more than 100 microns (μm).

24. The apparatus of claim 22, wherein the means for coupling the first die to the substrate comprises means for coupling the first die to the first set of traces of the substrate.

25. The apparatus of claim 22, wherein the means for coupling the second die to the substrate comprises means for coupling the second die to the second set of traces of the substrate.

26. The apparatus of claim 21 further comprising means for coupling a third die to the substrate of the IC package by the reflow bonding process, wherein the second die and the third die are coupled to the substrate in parallel during the same reflow bonding process.

27. The apparatus of claim 26, wherein the reflow bonding process is concurrently applied to the second die and the third die after the first die is coupled to the substrate by the thermal compression bonding process.

28. The apparatus of claim 21, wherein the first die is coupled to the substrate before the second die during an assembly process of the IC package.

29. The apparatus of claim 21, wherein the thermal compression bonding process has a lower units per hour (UPH) value than a UPH value of the reflow bonding process, the UPH value defining a number of units that can be manufactured during a given amount of time.

30. The apparatus of claim 21, wherein the first die has a first density connection with the substrate, the second die having a second density connection with the substrate that is less than the first density connection.

31. A computer readable storage medium comprising one or more instructions for manufacturing an integrated circuit (IC) package, which when executed by at least one processor, causes the at least one processor to:
couple a first die to a substrate of the IC package by a thermal compression bonding process; and
couple a second die to the substrate of the IC package by a reflow bonding process.

32. The computer readable storage medium of claim 31, wherein the substrate has a first set of traces and a second set of traces, the first set of traces having a first pitch, the second set of traces having a second pitch, the first pitch being less than the second pitch, wherein a pitch defines a center to center distance between two neighboring traces.

33. The computer readable storage medium of claim 32, wherein the first pitch is a pitch of 100 microns (μm) or less, the second pitch having a pitch of more than 100 microns (μm).

34. The computer readable storage medium of claim 32, wherein the one or more instructions for coupling the first die to the substrate comprises one or more instructions for coupling the first die to the first set of traces of the substrate.

35. The computer readable storage medium of claim 32, wherein the one or more instructions for coupling the second die to the substrate comprises one or more instructions for coupling the second die to the second set of traces of the substrate.

36. The computer readable storage medium of claim 31 further comprising one or more instructions for coupling a third die to the substrate of the IC package using the reflow bonding process, wherein the second die and the third die are coupled to the substrate in parallel during the same reflow bonding process.

37. The computer readable storage medium of claim 36, wherein the reflow bonding process is concurrently applied to the second die and the third die after the first die is coupled to the substrate by the thermal compression bonding process.

38. The computer readable storage medium of claim 31, wherein the first die is coupled to the substrate before the second die during an assembly process of the IC package.

39. The computer readable storage medium of claim 31, wherein the thermal compression bonding process has a lower units per hour (UPH) value than a UPH value of the reflow bonding process, the UPH value defining a number of units that can be manufactured during a given amount of time.

40. The computer readable storage medium of claim 31, wherein the first die has a first density connection with the substrate, the second die having a second density connection with the substrate that is less than the first density connection.
